(19) United States
(12) Patent Application Publication
(10) Pub. No.: US 2011/0221035 A1
(43) Pub. Date: Sep. 15, 2011

(54) PROCESS FOR FABRICATING AN INTEGRATED CIRCUIT INCLUDING A METAL-INSULATOR-METAL CAPACITOR AND CORRESPONDING INTEGRATED CIRCUIT

(75) Inventors: Simon Jeannot, Grenoble (FR); Michel Marty, Varces (FR); Jean-Christophe Giraudin, Saint-Nazaire les Eymes (FR)

(73) Assignee: STMICROELECTRONICS S.A., Montrouge (FR)

(21) Appl. No.: 13/034,373

(22) Filed: Feb. 24, 2011

(30) Foreign Application Priority Data
Mar. 9, 2010 (FR) 1051687

(51) Int. Cl. H01L 29/92; H01L 21/02

(52) U.S. Cl. 257/532; 438/381; 257/E29.342; 257/E21.008

(57) ABSTRACT

An integrated circuit is fabricated by producing metallization levels in insulating regions, the insulating region being formed of a first material having a first dielectric constant. At least one metal-insulator-metal capacitor is formed by providing metal electrodes in the metallization level, and locally replacing the first material, which is located between the metal electrodes, with a second material having a second dielectric constant greater than the first dielectric constant.

### PRIORITY CLAIM

This application claims priority from French Application for Patent No. 1051687 filed Mar. 9, 2010, the disclosure of which is hereby incorporated by reference.

### TECHNICAL FIELD

The invention relates to the field of microelectronic devices, and more particularly to metal-insulator-metal capacitive microelectronic devices.

### BACKGROUND

It is known to produce MIM (metal-insulator-metal) capacitors in integrated circuits. It is, moreover, advantageous for the dielectric region of such capacitors to have a relatively high dielectric constant so as to increase the capacitance of these capacitors.

U.S. Pat. No. 7,553,736 describes a treatment process consisting in treating, with a plasma-assisted chemical treatment, the dielectric region in which the capacitor is produced, so as to increase the dielectric constant of the dielectric material. With this treatment, —Si—CH₃ surface groups of the dielectric material are replaced with —Si—OH or —Si—H groups.

However, such a plasma treatment not only depends on the chemical composition of the dielectric material but also damages the top surface of the electrodes and the top surface of the dielectric region, necessitating a chemical-mechanical polish that removes a portion of the top part of the device.

### SUMMARY

According to one implementation and embodiment, it is proposed to produce a high-k metal-insulator-metal capacitor that performs better than conventional capacitors, costs less, and can be used with advanced technologies such as 45 nm and sub-45 nm technologies.

According to one implementation and embodiment, a process is proposed that allows the invention to be integrated with the greatest of ease into a conventional integrated-circuit BEOL (back end of line) interconnect process.

It is also proposed, in one embodiment, that the capacitor be produced in just one metallization level with a possible direct connection to the same metallization level.

It is also proposed, according to another implementation and embodiment, to produce three-dimensional capacitors with a stackable architecture.

According to one aspect, a process for fabricating an integrated circuit is proposed that comprises producing metallization levels within insulating regions comprising a first material having a first dielectric constant, for example a conventional low-k intermetallic dielectric, and producing at least one metal-insulator-metal capacitor comprising the formation of metal electrodes in at least one metallization level.

According to a general feature of this aspect, the production of the capacitor comprises locally replacing the first material, located between the metal electrodes, with at least one second material having a second dielectric constant greater than the first dielectric constant.

In other words, it is not a question of a chemical treatment of the first material leading to a transformed first material but indeed a total replacement of the low-k first material located between the electrodes with a higher-k second material, that is to say, locally removing the first material then filling the free space resulting from said local removal with the second material.

By way of indication, the second dielectric constant is greater than or equal to 6, for example between 20 and 50, although dielectric constants of the order of 1000 and beyond may be envisaged. Moreover, the first dielectric constant is less than 6.

According to one implementation, the local replacement of the first material with the second material comprises selectively etching the first material and depositing the second material in the cavity resulting from said selective etch.

According to one implementation, provision is also made for producing at least one additional metallization level above the capacitor, after production of the latter.

Generally, the production of each metallization level comprises forming a barrier layer, typically an SiCN/SiN layer, on the immediately underlying metallization level.

Several variants are then possible.

According to a first variant, the local replacement of the first material with the second material may be carried out before said barrier layer of the additional metallization level is formed, enabling the use of a lower quality mask.

According to another variant, the local replacement of the first material with the second material may be carried out after said barrier layer of the additional metallization level is formed. It is then preferable to use a high quality mask, for example of an equivalent quality to that of masks for forming metal lines.

The BEOL (back end of line) interconnect part of an integrated circuit comprises generally metallization levels mutually interconnected by vias levels. A metallization level comprises metallic lines. At least one metallic lines of a metallization level may be connected to at least one metallic line of another metallization level by a via of the vias level located between these two metallization levels.

According to an embodiment, the metal electrodes of the capacitor are formed within at least one metallization level, excluding metal electrodes formed in stacks of metallic lines and vias for example by using a dual Damascene process.

Thus with such an embodiment, a better precision of the capacity value is obtained because the thickness of the dielectric material depends only from the space between two metallic lines excluding any line/via space.

Further the leakage and the defaults of the capacitor are better overcome because there do not depend from any alignment via/line.

It is further possible to realize routing and/or a RF shield in the metallization level which is immediately under a metallization level containing the capacitor electrodes.

At last, such an embodiment is compatible with any usual technologies and design rules which generally do neither allow “trench” vias nor vias not contacting a lower metallic line.

The capacitor electrodes may be produced in just one metallization level.

As a variant, electrodes located on several superposed metallization levels may be produced.

Whatever the embodiment, interdigitated electrodes may be produced.

According to another aspect, an integrated circuit is proposed that comprises an interconnect part comprising metallization levels produced within insulating regions comprising a first material having a first dielectric constant and at least one metal-insulator-metal capacitor comprising metal electrodes that one placed on at least one metallization level and surrounded directly or indirectly by the first material. The capacitor also comprises, between the metal electrodes, a second material having a second dielectric constant, the second dielectric constant being higher than the first dielectric constant.

According to one embodiment, the electrodes are located in just one metallization level.

As a variant, they may be located in several adjacent metallization levels.

The electrodes may be interdigitated.

According to one embodiment, the interconnect part comprises at least one additional metallization level above the metallization level that contains the electrodes of the capacitor.

### BRIEF DESCRIPTION OF THE DRAWINGS

Other features and advantages of the invention will become apparent upon reading the following description given merely by way of non-limiting example and with reference to the appended drawings in which:

FIGS. 1 to 5 show the principal steps of one implementation of a fabrication process according to the invention;

FIG. 6 shows an embodiment of an integrated circuit according to the invention comprising an interdigitated-structure capacitor;

FIGS. 7 to 12 show the principal steps of another implementation of a fabrication process according to the invention;

FIG. 13 shows another embodiment of an intergrated circuit according to the invention comprising an interdigitated-structure capacitor; and

FIGS. 14 to 17 show the principal steps of another implementation of a fabrication process according to the invention.

### DETAILED DESCRIPTION OF THE DRAWINGS

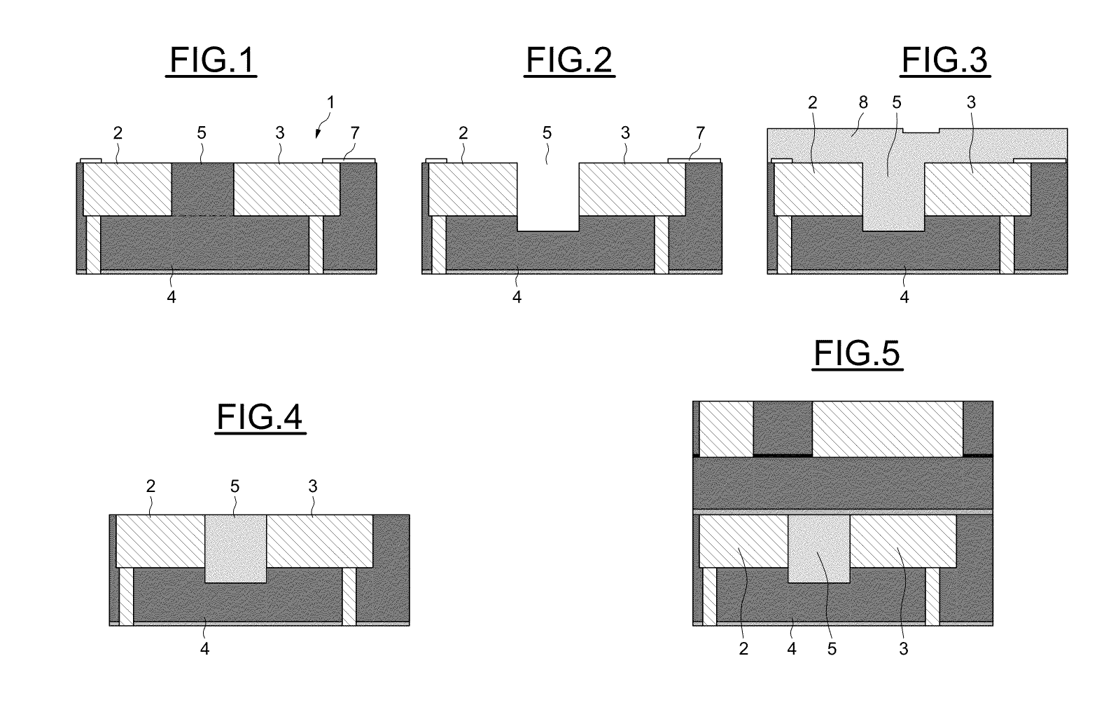

FIG. 1 shows a metallization level of the BEOL (back end of line) interconnect part of an integrated circuit comprising a capacitor 1 comprising two metal electrodes (2, 3) separated from each other by a dielectric material 4.

The dielectric material 4 extends not only beneath the metal tracks of the metallization level but also into the region 5 separating the metal electrodes of the capacitor.

The dielectric material 4 is a material conventionally used to produce the metallization levels of the BEOL part of the integrated circuit. It is, in general, a low-k material. In this regard, the expression “low-k material” should be understood here to mean a material the dielectric constant k of which is less than 6. Amongst the low-k dielectric materials conventionally used, carbon-doped silicon oxides or fluorine-doped silicon oxides may be mentioned.

Generally, once a metallization level is produced it covered with a barrier layer, for example conventionally formed from SiCN or from SiN, before the dielectric material 4 of the metallization level lying immediately above it is deposited.

In the implementation shown in FIGS. 1 to 5, the high-k capacitor will be produced before the deposition of this barrier layer.

It is for this reason that, in FIG. 1, no barrier layer is shown on the top surface of the metal electrodes 2 and 3, nor on the top surface of the low-k dielectric material 4 placed in the separation region 5.

The surface is then coated with a photoresist layer 7 that is patterned so as to make the separation region 5 and a part of the metal electrodes (2, 3) accessible, the rest of the device being masked.

The process continues (FIG. 2) with a selective etch of the material 4 in the separation region 5 located between the two metal electrodes (2, 3). The etch is selective to the metal forming the electrodes, that is to say that the metal is not etched whilst the dielectric material is removed.

Such a selective etch is conventional and known per se and may be carried out for example by dry plasma etching with a CF₄, C₄F₈ and N₂ gas mixture or by wet etching using hydrofluoric acid, glycolic acid or organic acid solutions.

The next step of the process is shown in FIG. 3. The resist layer 7 is removed and a high-k dielectric layer 8 is deposited conformally so as to fill the cavity resulting from the selective etch of the separation region 5. The high-k dielectric layer 8 is deposited on the entire wafer and therefore also covers the metal electrodes (2, 3) and the exposed part of the dielectric layer 4.

The expression “high-k material” should be understood here to mean a material the dielectric constant of which is greater than 6. However, such a dielectric constant is generally between 20 and 50 and may even reach values of the order of 1000 and beyond for certain materials.

High-k materials are well known to those skilled in the art. In particular, tantalum pentoxide Ta₂O₅, zirconium oxide ZrO₂, PZT (lead zirconate titanate) or indeed nanoparticle-containing polymers may be mentioned.

These materials may be deposited, for example conformally deposited, using chemical vapor methods such as PECVD or MOCVD or else deposited by atomic layer deposition methods such as ALD or PEALD or else by the spin coating of high-k sol-gel materials.

Those skilled in the art may also refer, for all practical purposes, to the following three articles that give examples of high-k materials and processes for implementing them:
the article by Yang Rao, entitled “Novel Ultra-high dielectric Constant Polymer Based Compositte for Embedded Capacitor Application”; IEEE Polytronic 2002 Conference;
the article by Michael D. Sacks et al., entitled “Low-Cost Embedded Capacitor Technology With Hydrothermal And Sol-Gel Processes”9^{th} International Symposium on Advanced Packaging Materials 2004 IEE; and,
the article by Troutman et al., entitled “Development and Low Viscocity, High Dielectric Constant (K) Polymers for Integral Passive Applications”, 1999 International Symposium on Advanced Packaging Materials.

The following step is a chemical-mechanical polish of the high-k dielectric layer 8. The polish is stopped once it reaches the top face of the metal electrodes (2, 3). A planar surface is then obtained at the junction between the metal electrodes (2, 3) and the separation region 5 filled with high-k dielectric material. This process step is shown in FIG. 4.

The fabrication process may be thus easily integrated into the conventional process for fabricating the interconnect part of the integrated circuit. More precisely, as shown in FIG. 5, a new barrier layer may be produced so as to isolate the metallization level containing the capacitor 1. Then, in a conventional manner, known per se, an additional metallization level is produced above this barrier layer by depositing the low-k dielectric material then etching this dielectric material to form trenches that will be filled with metal to form metal tracks.

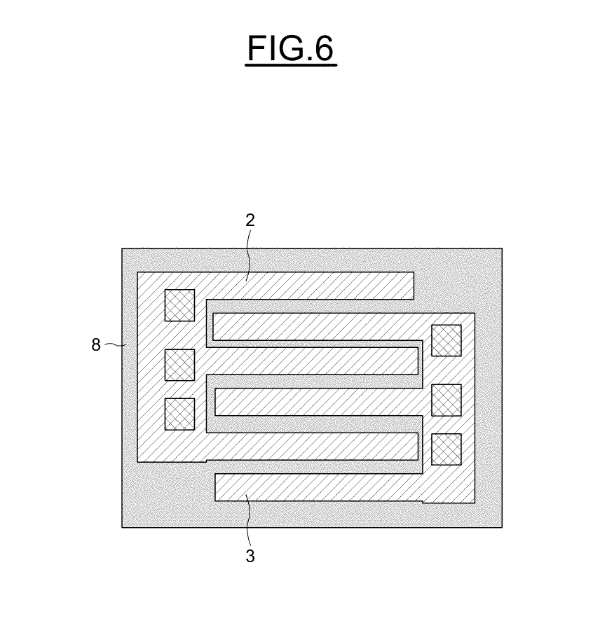

FIG. 6 shows a top view of an example of a capacitor 1 and metal electrodes (2, 3).

The metal electrodes 2 and 3 of the capacitor here are interdigitated while being compact and produced within just one metallization level.

Moreover, in this example, the high-k dielectric material 8 is located not only between the metal electrodes but also, to a slight extent, around them because the etch mask which enabled the low-k dielectric to be etched level with the metallization was a lower quality mask that extended slightly beyond the electrodes.

The material 8 is surrounded by low-k material 4 (not shown here, see, FIG. 4).

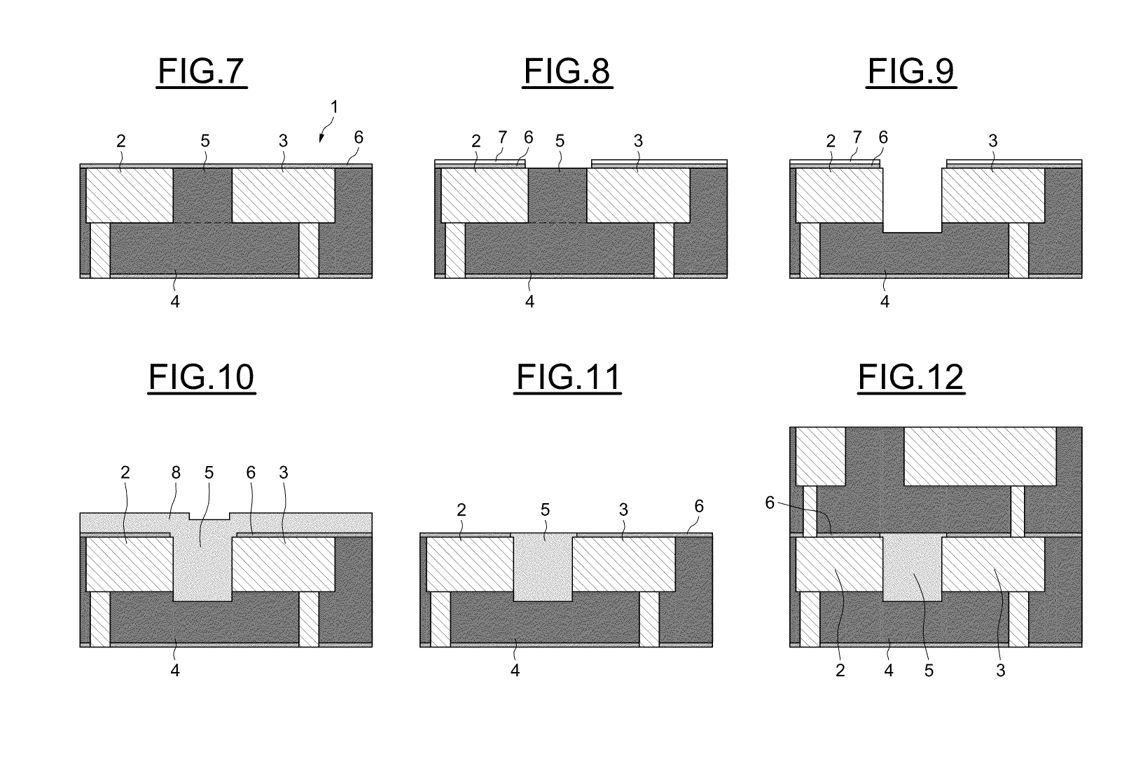

Another implementation of the process according to the invention is shown in FIGS. 7 to 12.

In this implementation, the local replacement of the dielectric material 4 with the high-k dielectric material 8 is carried out after the barrier layer 6 has been deposited (FIG. 7).

As shown in FIG. 8, a resist mask 7 is deposited on the barrier layer 6, which mask will enable a part of the underlying barrier layer 6 to be removed by selective etching.

Next, in an analogous manner to that described above with reference to FIGS. 3 to 5, the dielectric material 4 is selectively etched in the region 5 separating the electrodes (FIG. 9), and then a high-k dielectric material 8 is deposited in the cavity resulting from the preceding etch and over the whole wafer (FIG. 10).

Next, FIG. 11, the layer 8 is chemically-mechanically polished stopping on the barrier layer 6 so as to obtain the structure shown in FIG. 11.

Here also, as shown in FIG. 12, the fabrication process may be continued by producing an additional metallization level above the barrier layer 6. By way of example, vias may be produced so as to connect the electrodes of the capacitor 1 to the tracks of this additional metallization level.

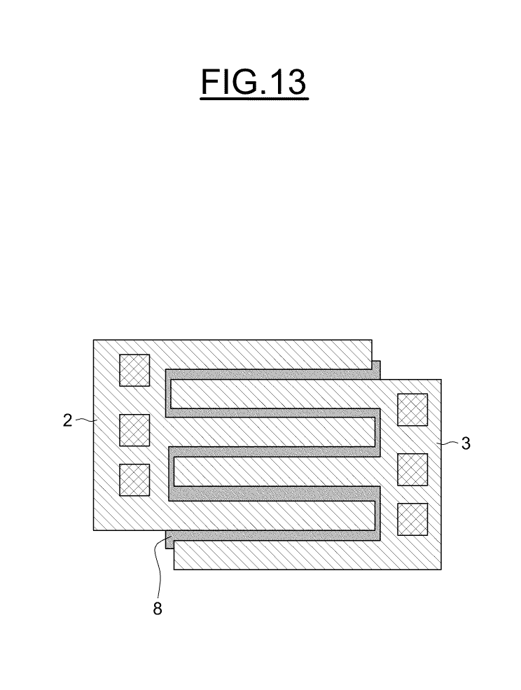

FIG. 13 shows a top view of the capacitor 1 and the metal electrodes (2, 3) of FIG. 12. As may be seen, the high-k dielectric layer 8 is deposited essentially in the region 5 separating the electrodes (2, 3).

This is because the mask used for the selective etch of the low-k dielectric material 4 is a higher quality mask which prevents there being any high-k material outside the electrodes, as in the case of FIG. 6.

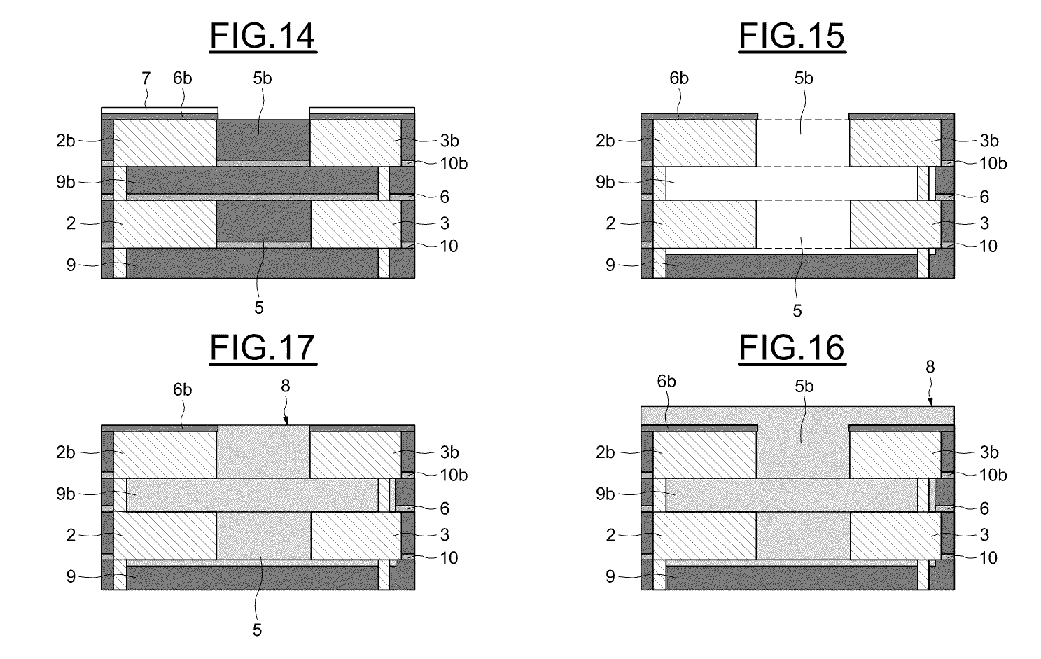

FIGS. 14 to 17 show another implementation of the process according to the invention for producing capacitors the electrodes of which extend over several superposed metallization levels, here two metallization levels.

As shown in FIG. 14, the capacitor here comprises a top part having two metal electrodes 2b and 3b and a bottom part having two metal electrodes 2 and 3.

The bottom and top part of the metal electrodes are connected by metal connection parts.

The separation regions 5 and 5b are again filled with low-k dielectric material. This material is also located above the barrier layer 6 in the region 9b located between the top electrodes 2b, 3b and the bottom electrodes 2 and 3.

Here again, analogously to the preceding implementation, the replacement of the low-k material with high-k material is carried out after the barrier layer 6b has been deposited on the metal electrodes 2b, 3b.

Analogously to what has been described above, after depositing a resist mask 7 the barrier layer 6b is locally etched, then the dielectric material located in the regions 5, 5b and 9b (FIG. 15) is etched.

Next, as explained above, a high-k dielectric material 8 is deposited in the cavities resulting from the preceding etch and over the entire wafer (FIG. 16). Next, after chemical-mechanical polishing of the top surface of the structure shown in FIG. 16, the structure shown in FIG. 17 is obtained.

A three-dimensional metal-insulator-metal capacitor is thus obtained formed from several stacked elementary capacitors produced, respectively, in superposed metallization levels. Moreover, the top and bottom electrodes may also be interdigitated. Lastly, the three-dimensional capacitor thus produced benefits from an additional capacitance by virtue of the high-k dielectric material present in the region 9b between the top and bottom electrodes.

What is claimed is:

1. A process, comprising:
producing metallization levels within insulating regions comprising a first material having a first dielectric constant, and
producing at least one metal-insulator-metal capacitor comprising the formation of metal electrodes in at least one metallization level,
wherein producing the capacitor comprises locally replacing the first material that is located between the metal electrodes with at least one second material having a second dielectric constant greater than the first dielectric constant.

2. The process according to claim 1, wherein the second dielectric constant is greater than or equal to six and the first dielectric constant is less than six.

3. The process according to claim 2, wherein the second dielectric constant is greater than twenty.

4. The process according to claim 1, wherein locally replacing comprises selectively etching the first material from between the metal electrodes, and depositing the second material in the cavity resulting from selectively etching.

5. The process according to claim 4 wherein selectively etching comprises forming a mask with an opening exposing a region at least between the metal electrodes and removing through the opening in the mask the first material from between the metal electrodes.

6. The process according to claim 1, further comprising producing at least one additional metallization level above the at least one metal-insulator-metal capacitor, after locally replacing the first material with the second material.

7. The process according to claim 6, wherein producing each metallization level comprises forming a barrier layer on an immediately underlying metallization level, and wherein the operation of locally replacing the first material with the second material is performed before said barrier layer is formed.

8. The process according to claim 6, wherein producing each metallization level comprises forming a barrier layer on an immediately underlying metallization level, and wherein the operation of locally replacing the first material with the second material is performed after said barrier layer is formed.

9. The process according to claim 1, wherein the metal electrodes for one capacitor are produced in just one metallization level.

10. The process according to claim 1, wherein the metal electrodes for one capacitor are produced in several superposed metallization levels.

11. The process according to claim 1, wherein the metal electrodes are formed with an interdigitated configuration.

12. An integrated circuit, comprising:
an interconnect part comprising metallization levels produced within insulating regions comprising a first material having a first dielectric constant,
at least one metal-insulator-metal capacitor comprising metal electrodes placed on at least one metallization level and surrounded directly or indirectly by said first material, and
a second material having a second dielectric constant positioned between the metal electrodes, the second dielectric constant being higher than the first dielectric constant.

13. The integrated circuit according to claim 12, wherein the first dielectric constant is less than six and the second dielectric constant is greater than six.

14. The integrated circuit according to claim 12, wherein the second dielectric constant is greater than twenty.

15. The integrated circuit according to claim 12, wherein the electrodes for one capacitor are located in just one metallization level.

16. The integrated circuit according to claim 12, wherein the electrodes for one capacitor are located in several superposed metallization levels.

17. The integrated circuit according to claim 12, wherein the metal electrodes have an interdigitated configuration.

18. The integrated circuit according to claim 12, wherein the interconnect part comprises at least one additional metallization level above the metallization level that contains the electrodes of the capacitor.

19. The integrated circuit according to claim 12, further comprising a barrier layer between superposed metallization levels.

20. A process, comprising:
producing an insulating layer for a first metallization level, the insulating layer formed of a first material having a first dielectric constant;
producing metal electrodes of a capacitor in the insulating layer of the first metallization level;
forming a mask over the insulating layer which includes an opening that exposes at least a region of the first material located between the metal electrodes;
removing, through the opening in the mask, the first material of the insulating layer from the region located between the metal electrodes to produce a cavity;
filling the cavity with a second material having a second dielectric constant that is greater than the first dielectric constant.

21. The process according to claim 20, wherein the second dielectric constant is greater than or equal to six and the first dielectric constant is less than six.

22. The process according to claim 20, further comprising forming a barrier layer over the insulating layer, and wherein the mask is formed over the barrier layer and the opening extends through both the mask and the barrier layer.

23. The process according to claim 20, further comprising:
producing an insulating layer for a second metallization level below the first metallization level, the insulating layer formed of the first material having the first dielectric constant; and
producing metal electrodes of the capacitor in the insulating layer of the second metallization level;
wherein removing comprises removing, through the opening in the mask, the first material of the insulating layers for the first and second metallization levels from the region located between the metal electrodes to produce a cavity in both the first and second metallization levels; and
wherein filling, comprises filling the cavity in both the first and second metallization levels with the second material having the second dielectric constant.

24. The process according to claim 20, wherein producing metal electrodes comprises producing metal electrodes with an interdigitated configuration.
